(19) United States
(12) Patent Application Publication
(10) Pub. No.: US 2013/0120011 A1
(43) Pub. Date: May 16, 2013

(54) SEMICONDUCTOR DEVICE AND METHOD OF DRIVING THE SAME

(71) Applicant: CANON KABUSHIKI KAISHA, Tokyo (JP)

(72) Inventors: Tatsuhiko Yamazaki, Zama-shi (JP); Hidetoshi Hayashi, Fujisawa-shi (JP); Takuro Yamamoto, Funabashi-shi (JP)

(73) Assignee: CANON KABUSHIKI KAISHA, Tokyo (JP)

(21) Appl. No.: 13/656,940

(22) Filed: Oct. 22, 2012

(30) Foreign Application Priority Data
Nov. 10, 2011 (JP) 2011-246855

(51) Int. Cl. G01R 31/26

(52) U.S. Cl. 324/750.3

(57) ABSTRACT

A semiconductor device including a plurality of sensor units and a plurality of storage units, the device comprising a controller which in a normal mode, sets first control information based on outputs from the plurality of sensor units, stores the first control information in the plurality of storage units, and accumulates charges in each of the plurality of sensor units up to a reference defined in the corresponding first control information, and in a test mode, stores second control information for tests determined in advance in the plurality of storage units, accumulates charges in each of the plurality of sensor units up to a reference defined in the corresponding second control information, and tests the plurality of sensor units based on the amounts of charges accumulated in the plurality of sensor units.

### BACKGROUND OF THE INVENTION

1. Field of the Invention

The present invention relates to a semiconductor device and a method of driving the same.

2. Description of the Related Art

Japanese Patent Laid-Open No. 11-150686 discloses a technique of providing photoelectric conversion units for focus detection, which correspond to respective distance measurement points for a camera, to set control information based on the output from each of these photoelectric conversion units. This control information is used to control, for example, a charge accumulation operation and a signal readout operation based on the accumulated charges, and can be set for each distance measurement point in normal use. This provides a semiconductor device which can achieve highly accurate focus detection.

Miniaturization of photoelectric conversion units for focus detection may lead to variations in characteristics of charge accumulation of the photoelectric conversion units. Also, complication and sophistication of a control system may cause a failure due to short-circuiting of sensor units including the photoelectric conversion units, or signal lines which control these sensor units. Therefore, the semiconductor device described in Japanese Patent Laid-Open No. 11-150686 is disadvantageous in terms of increasing the efficiency of tests for these malfunctions.

### SUMMARY OF THE INVENTION

The present invention provides a technique advantageous in terms of increasing the efficiency of tests for malfunctions of a semiconductor device.

One of the aspects of the present invention provides a semiconductor device including a plurality of sensor units, and a plurality of storage units corresponding to the plurality of sensor units, respectively, the device comprising a controller which in a normal mode, sets a plurality of pieces of first control information based on outputs from the plurality of sensor units, respectively, stores the plurality of pieces of first control information in the plurality of storage units, respectively, and accumulates charges in each of the plurality of sensor units up to a reference defined in the corresponding first control information, and in a test mode, stores a plurality of pieces of second control information for tests determined in advance in the plurality of storage units, respectively, accumulates charges in each of the plurality of sensor units up to a reference defined in the corresponding second control information, and tests the plurality of sensor units based on the amounts of charges accumulated in the plurality of sensor units.

Further features of the present invention will become apparent from the following description of exemplary embodiments with reference to the attached drawings.

### BRIEF DESCRIPTION OF THE DRAWINGS

FIGS. 1A and 1B are circuit diagrams for explaining a configuration according to the first embodiment of the present invention;

FIG. 2 is a circuit diagram for explaining a configuration according to the second embodiment of the present invention;

FIGS. 3A and 3B are main flowcharts of the second embodiment;

FIGS. 4A and 4B are sub-flowcharts of the second embodiment;

FIGS. 5A and 5B are plots for explaining the amounts of accumulated charges according to the second embodiment;

FIG. 6 is a circuit diagram for explaining a configuration according to the third embodiment of the present invention;

FIGS. 7A and 7B are main flowcharts of the third embodiment;

FIGS. 8A and 8B are sub-flowcharts of the third embodiment;

FIG. 9 is a plot for explaining the amounts of accumulated charges according to the third embodiment;

FIG. 10 is a sub-flowchart of the fourth embodiment; and

FIGS. 11A to 11D illustrate examples of the internal configuration of respective functional blocks.

### DESCRIPTION OF THE EMBODIMENTS

### First Embodiment

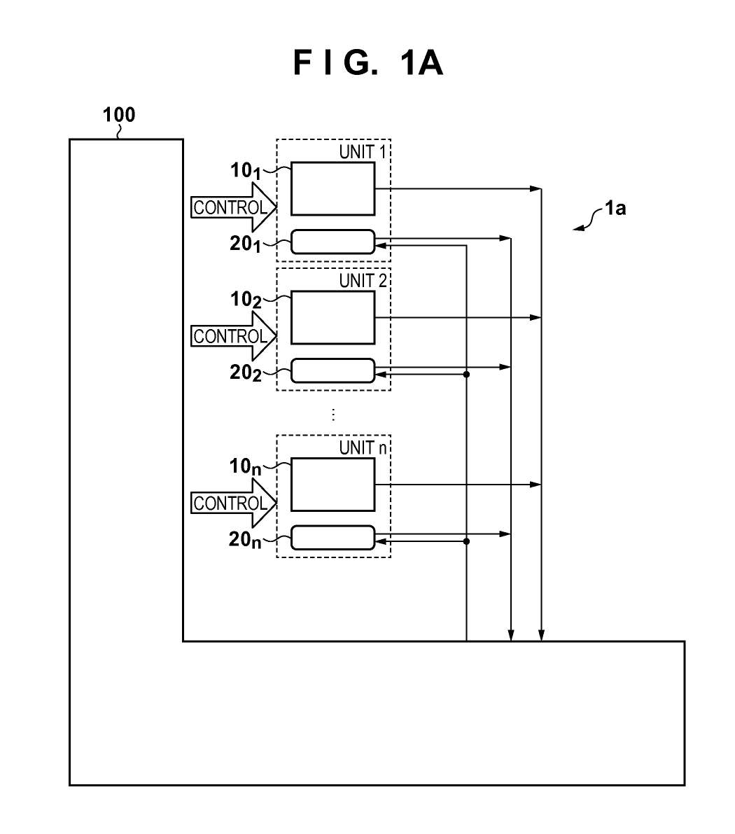

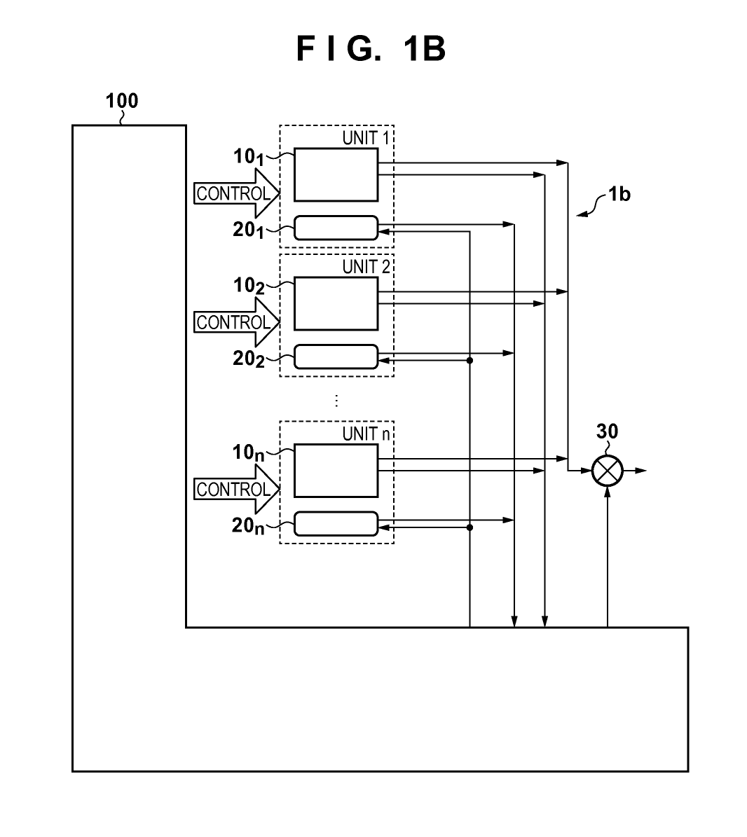

A semiconductor device 1a according to the first embodiment of the present invention will be described first with reference to FIG. 1A. The semiconductor device 1a includes a plurality of units k (k=1 to n) corresponding to respective distance measurement points, and a control unit 100 which controls these units. The plurality of units k include a plurality of sensor units 10ₖ, and a plurality of storage units 20ₖ corresponding to the plurality of sensor units 10ₖ, respectively. Although the sensor units 10ₖ and storage units 20ₖ are juxtaposed in one-to-one correspondence with the units k, respectively, in FIGS. 1A and 1B, they need not always be arranged near each other, and their arrangement may be changed in accordance with the chip layout. Also, each sensor unit 10ₖ may include a photoelectric conversion unit for focus detection including a light-receiving element such as a photodiode, a readout unit 12ₖ which reads out a signal output from the photoelectric conversion unit, and a charge holding unit which holds the charges in the photoelectric conversion unit, in accordance with each function to be described later.

The semiconductor device 1a includes a normal mode and a test mode as operation modes. In the normal mode, the control unit 100 sets first control information based on the output from each of the plurality of sensor units 10ₖ, and stores it in the corresponding one of the plurality of storage units 20ₖ. The control unit 100 then performs an operation of accumulating charges in each sensor unit 10ₖ up to a reference defined in the first control information stored in the corresponding one of the plurality of storage units 20ₖ. With this operation, in the normal mode, a charge accumulation operation in the sensor unit 10ₖ can be controlled in accordance with the output from the sensor unit 10ₖ as it detects, for example, external input information.

On the other hand, in the test mode, the control unit 100 stores a plurality of pieces of second control information for tests, that are determined in advance, in the plurality of storage units 20ₖ, respectively. The control unit 100 then accumulates charges in each sensor unit 10ₖ up to a reference defined in the second control information stored in the corresponding one of the plurality of storage units 20ₖ, and tests the amounts of charges accumulated in the plurality of sensor units 10ₖ. That is, in the test mode, the control unit 100 performs an operation of accumulating charges determined in advance in the plurality of sensor units 10ₖ. Hence, when a signal output from each sensor unit 10ₖ based on the amount of accumulated charges has a value different from a desired value, this means that this sensor unit 10ₖ or its control signal has a malfunction.

The semiconductor device 1a shown in FIG. 1A is applicable to a focus detection apparatus included in, for example, a camera. As a commonly used scheme, the focus detection apparatus can control the accumulation time in accordance with the luminance level of an object in focus detection. In this embodiment, in the normal mode, first, first control information for controlling an accumulation operation in accordance with the luminance level of an object can be set. In a subsequent process of detecting the focus, the control unit 100 accumulates charges in each sensor unit 10ₖ up to a reference defined in the first control information stored in the corresponding one of the plurality of storage units 20ₖ. Based on signals output in accordance with the amounts of accumulated charges, a calculation unit (for example, a defocus amount detection unit (not shown)) for performing a calculation process performs a predetermined calculation process. The calculation result is fed back to a focusing unit (for example, a lens driving unit (not shown)) for adjusting the focus, so the focus of a lens can be adjusted. On the other hand, in the test mode, second control information determined in advance is stored in each of the plurality of storage units 20ₖ. With this operation, charges are accumulated in each of the plurality of sensor units 10ₖ up to a reference determined in advance in accordance with the second control information. Hence, each sensor unit 10ₖ outputs a signal indicating a desired output value if it has no malfunction, or outputs a signal indicating an undesired output value if it has a malfunction. This makes it possible to distinguish between the signals output from the plurality of sensor units 10ₖ to detect a malfunction even under, for example, uniform irradiation light.

Also, FIG. 1B shows a semiconductor device 1b according to a modification to the semiconductor device 1a. The semiconductor device 1b further includes an amplifier unit 30, which can amplify a signal output from the sensor unit 10ₖ in accordance with a set amplification factor, and output it. For example, in the normal mode, the control unit 100 can also set an amplification factor based on the first control information stored in each of the plurality of storage units 20ₖ. This makes it possible to perform focus detection with higher accuracy, in addition to the above-mentioned effect of controlling the charge accumulation operation. More specifically, at a high luminance level, a reduction in amount of accumulated charges and selection of a low amplification factor make it possible to prevent the signal output from the semiconductor device 1b from exceeding the dynamic range of a pixel signal that can be processed by the apparatus. At a low luminance level, prolonging the accumulation time makes it possible to ensure a sufficient amount of charges to suppress the adverse effect of noise relative to the amount of charges, thereby selecting a high amplification factor.

On the other hand, in the test mode, the control unit 100 can set an amplification factor determined in advance. The control unit 100 can set the amplification factor to, for example, a unique value. At this time, the amplifier unit 30 can amplify a signal output from the sensor unit 10ₖ in accordance with an amplification factor having the unique value, and output it. Note that the signal output from the sensor unit 10ₖ is determined in accordance with the amount of charges accumulated to a reference defined in the second control information determined in advance. Hence, the semiconductor device 1b outputs a signal indicating a desired output value if it has no malfunction, or outputs a signal indicating an undesired output value if it has a malfunction. This makes it possible to detect a malfunction even under uniform irradiation light in this case as well.

### Second Embodiment

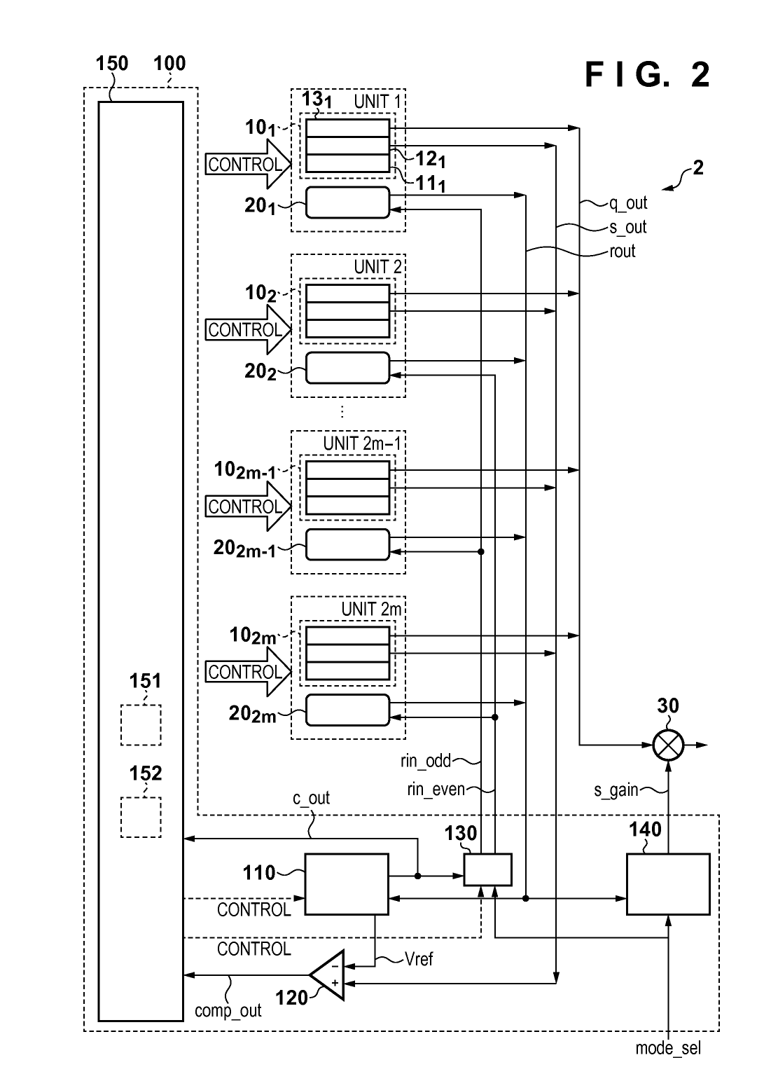

The second embodiment of the present invention will be described with reference to FIGS. 2 to 5A and 5B. FIG. 2 shows a focus detection apparatus 2 according to the second embodiment. The focus detection apparatus 2 includes a plurality of sensor units 10, a plurality of storage units 20 corresponding to the plurality of sensor units 10, respectively, an amplifier unit 30 which amplifies a signal output from the sensor unit 10 in accordance with a set amplification factor, and outputs it, and a control unit 100 which controls these units. Also, each of the plurality of sensor units 10 includes a photoelectric conversion unit 11 which outputs a signal corresponding to the amount of charges accumulated by charge accumulation, a readout unit 12 which reads out the signal output from the photoelectric conversion unit 11, and a charge holding unit 13 which holds the charges accumulated in the photoelectric conversion unit 11. Moreover, the control unit 100 includes a reference setting unit 110 which outputs a reference potential Vref to be compared with a signal output from the readout unit 12, and a comparison unit 120 which compares the signal output from the readout unit 12 with the reference potential Vref. The control unit 100 also includes an initial setting unit 130, an amplification factor setting unit 140, and a mode setting terminal mode_sel which selects the normal mode or the test mode as an operation mode, and can thereby switch the operations of the initial setting unit 130 and amplification factor setting unit 140. For example, as in this embodiment, the normal mode can be set by mode_sel=Low, and the test mode can be set by mode_sel=Hi. The control unit 100 moreover includes a controller 150 which communicates information with these units to issue an instruction of each operation.

FIG. 2 shows the sensor units 10 and storage units 20 in one-to-one correspondence with units k (k=1, 2, . . . , 2m−1, 2m). However, as in the first embodiment, these units need not always be arranged near each other, and their arrangement may be changed in accordance with the chip layout. Note that the last unit is defined as a unit n (n=2m (even number)).

A photoelectric conversion unit 11ₖ is formed by a pair of sensor arrays for the phase-difference detection method, and can form two images using, for example, about 30 to 80 pixels. A readout unit 12ₖ can detect the amount of charges accumulated in the photoelectric conversion unit 11ₖ, and output, for example, a peak value among the outputs from the plurality of pixels of the photoelectric conversion unit 11ₖ. Also, for example, not only a peak value but also a bottom value may be detected to use a peak—bottom signal obtained from their difference. This output result can be output to the comparison unit 120 as a signal s_out in accordance with an instruction from the controller 150. A charge holding unit 13ₖ can temporarily hold as a pixel signal q_out the charges accumulated in the photoelectric conversion unit 11ₖ. The pixel signal q_out can be output to the amplifier unit 30 in accordance with an instruction from the controller 150.

A storage unit 20ₖ can store control information (first control information or second control information), associated with charge accumulation in the photoelectric conversion unit 11ₖ, in accordance with an instruction from the controller 150. This control information may be, for example, 2-bit information (“0” to “3”), as in this embodiment. Also, this control information can be output to the reference setting unit 110 and amplification factor setting unit 140 in accordance with an instruction from the controller 150. In this embodiment, depending on whether each storage unit 20ₖ corresponds to the sensor unit 10ₖ of an odd- or even-numbered unit, the signal line connected to this storage unit 20ₖ to store control information is changed between different inputs rin_odd and rin_even. Note that the storage unit 20ₖ of each odd-numbered unit has rin_odd as an input and rout as an output, and the storage unit 20ₖ of each even-numbered unit has rin_even as an input, and rout as an output.

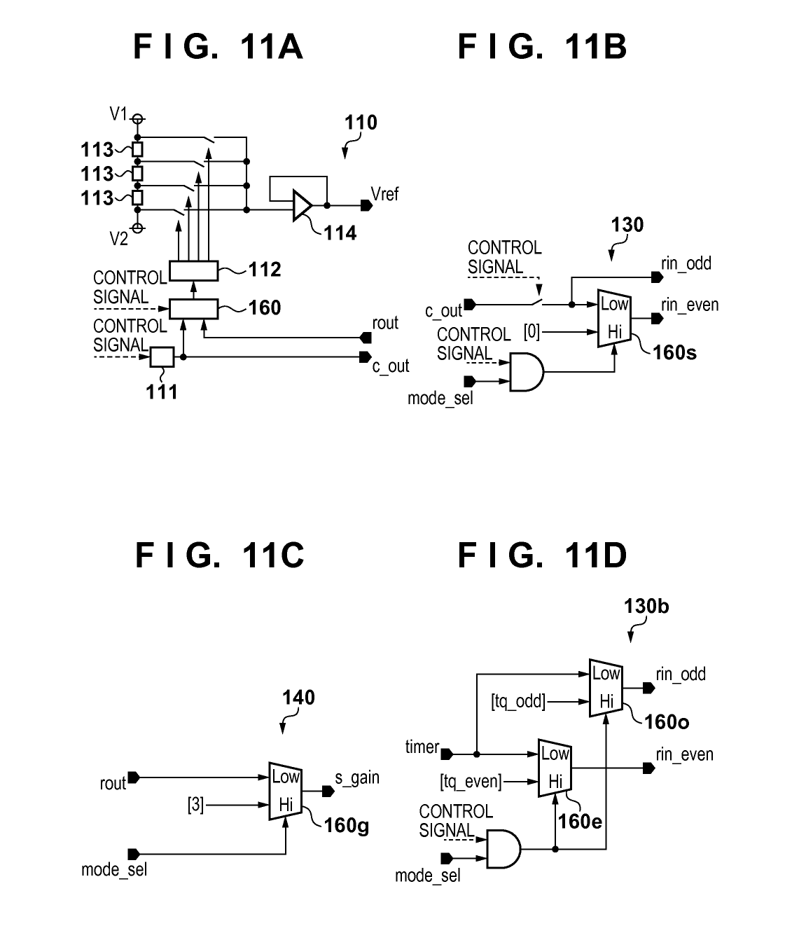

The reference setting unit 110 may have a configuration as shown in, for example, FIG. 11A, and can include a counter 111, a selector 160, a decoder 112, a plurality of resistors 113, and an amplifier 114. The counter 111 can be used to compare a signal output from the readout unit 12ₖ with the reference potential Vref. The selector 160 can select one of a measurement result c_out obtained by the counter 111, and control information from the storage unit 20ₖ. The decoder 112 can generate a control signal for selecting the reference potential Vref based on the output from the selector 160. The amplifier 114 can output these control signals and reference potentials Vref generated by the plurality of resistors 113. The reference setting unit 110 can selectively read out the control information stored in each of the plurality of storage unit 20ₖ in accordance with an instruction from the controller 150 to generate a reference potential Vref to be compared with the signal output from the readout unit 12ₖ, and output the reference potential Vref to the comparison unit 120. The reference setting unit 110 can also output the measurement result c_out obtained by the counter 111. The measurement result c_out can be input to the initial setting unit 130 in accordance with an instruction from the controller 150. The comparison unit 120 can compare the signal s_out read out from the readout unit 12ₖ with the reference potential Vref, and output a comparison result comp_out to the controller 150. In this embodiment, comp_out=Hi is set for s_out Vref.

The initial setting unit 130 can select the normal mode or the test mode as an operation mode upon setting of the mode setting terminal mode_sel. With this operation, in the normal mode, each storage unit 20ₖ can store first control information (the measurement result c_out obtained by the counter 111; to be described later) associated with charge accumulation in the photoelectric conversion unit 11ₖ. On the other hand, in the test mode, second control information determined in advance can be stored. The initial setting unit 130 may have a configuration as shown in, for example, FIG. 11B, and its two output terminals can be connected to signal lines for transmitting rin_odd and rin_even, respectively, in FIG. 2. Note that when the mode setting terminal is at Hi, “0” is output to rin_even. That is, in the test mode, control information “0” can be stored in the storage unit 20ₖ of each even-numbered unit as second control information. Also, the measurement result c_out obtained by the counter 111 (to be described later) is output to rin_odd, and can be stored in the storage unit 20ₖ of each odd-numbered unit as second control information.

The amplification factor setting unit 140 selects the normal mode or the test mode as an operation mode upon setting of the mode setting terminal mode_sel to set control information which specifies an amplification factor for amplifying the signal q_out output from the charge holding unit 13ₖ. The amplification factor setting unit 140 may have a configuration as shown in, for example, FIG. 11C. With this operation, first control information read out from each of the plurality of storage units 20ₖ is selected in the normal mode, and control information having a unique value (“3” in this embodiment) stored in advance is selected in the test mode. Then, the amplifier unit 30 can amplify the signal q_out output from the charge holding unit 13ₖ in accordance with an amplification factor set by the amplification factor setting unit 140, and output it.

The controller 150 can communicate with these functional blocks and issue operation instructions, in accordance with execution programs. The execution programs may be stored in a program memory 151 included in the controller 150, as shown in FIG. 2.

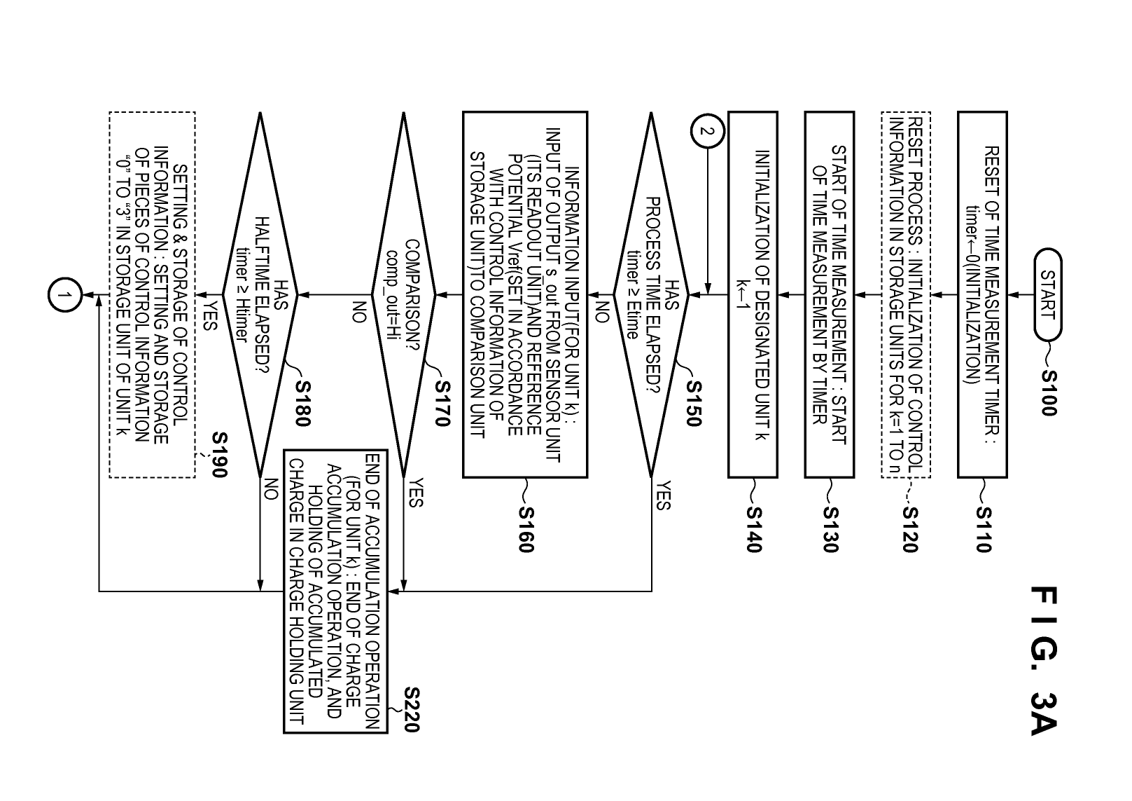

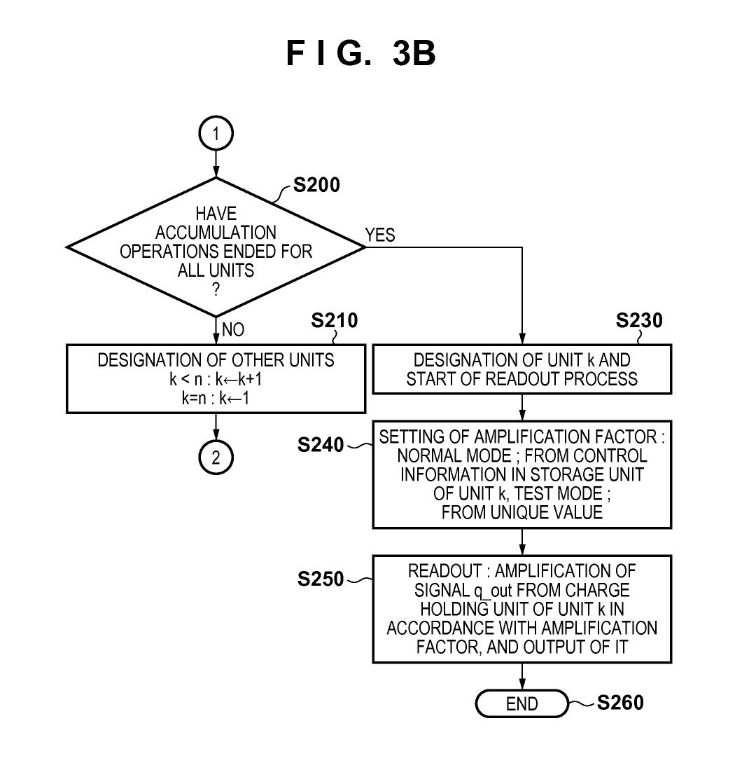

The operations of the focus detection apparatus 2, shown in flowcharts of, for example, FIGS. 3A and 3B, can be achieved by making the controller 150 execute the execution program. Also, both the operation modes, that is, the normal mode and the test mode can be achieved by the execution program according to this flowchart. These operations will be described below individually for the normal mode and test mode. The operation in the normal mode will be described first. In step S100, the execution program starts. In step S110, the value of “timer” of a timer 152 (included in, for example, the controller 150) is initialized (timer=0).

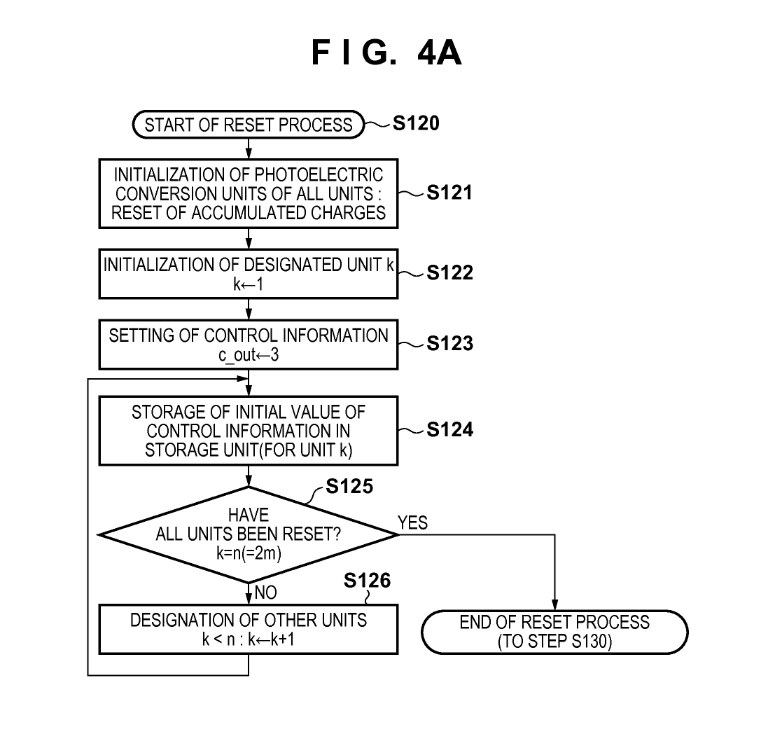

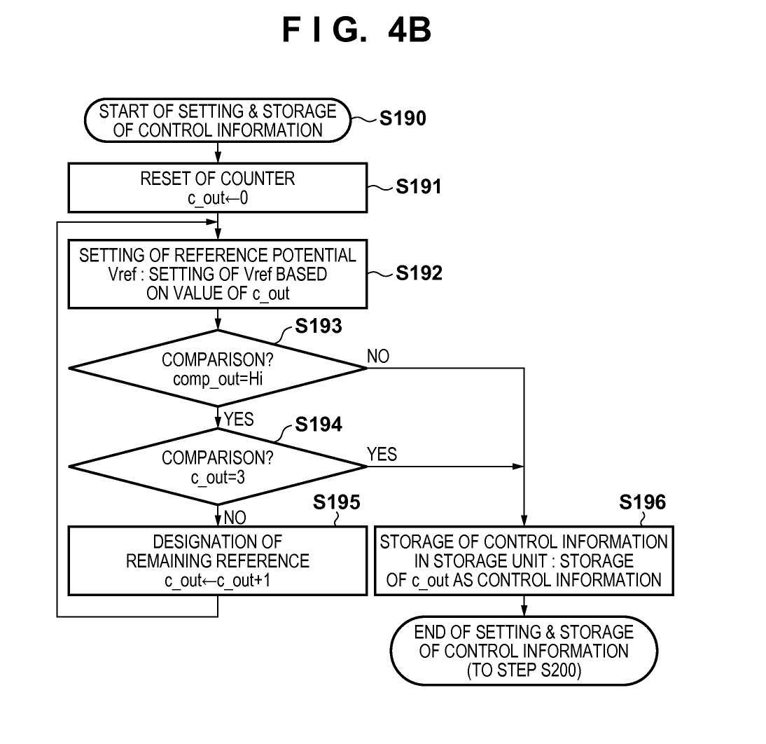

In step S120, a reset process according to a flowchart (steps S120-S126) shown in, for example, FIG. 4A is performed. First, in accordance with an instruction from the controller 150, the charges accumulated in the photoelectric conversion unit 11ₖ is reset (step S121), and charge accumulation then starts. Also, in the reset process of the normal mode, control information to be stored in each of the plurality of storage units 20ₖ is initialized (for example, “3” is set (step S123)), and stored in the corresponding one of the storage units 20ₖ of all units (steps S122, S124, S125, & S126). Control information “3” having the initial value may be stored based on, for example, the output c_out from the counter 111 (FIG. 11A), in accordance with an instruction from the controller 150, as in this embodiment. In step S130, the timer 152 starts time measurement (the value of “timer” is incremented with time), which may be done by executing the program.

In step S140, the value of a register (not shown) for designating the unit k is initialized (k=1). In step S150, the controller 150 determines whether the value of “timer” exceeds the upper limit (Etime) of the charge accumulation time set in advance. If timer≧Etime, the process advances to step S220 (to be described later). If timer<Etime, the process advances to step S160. In step S160, in accordance with an instruction from the controller 150, the output s_out from the readout unit 12ₖ, and the reference potential Vref based on the control information stored in the storage unit 20ₖ are input to the comparison unit 120 for the unit k. In step S170, the comparison unit 120 compares s_out and Vref set in step S160. At this time, if the output from the comparison unit 120 is comp_out=Hi (s_out≧Vref), the process advances to step S220 (to be described later). If the output from the comparison unit 120 is comp_out=Low (s_out<Vref), the process advances to step S180. In step S180, the controller 150 determines whether the value of “timer” exceeds a halftime (Htime) set in advance. If timer≧Htime, the process advances to step S190. If timer<Htime, the process advances to step S200 (to be described later). In step S190, the controller 150 sets control information (first control information) corresponding to the amount of charges accumulated in the photoelectric conversion unit 11ₖ of the unit k, and stores it in the storage unit 20ₖ. The first control information is determined based on the amount of charges accumulated in the photoelectric conversion unit 11ₖ, the reference potential Vref output from the reference setting unit 110 in accordance with an instruction from the controller 150, and the result obtained by the comparison unit 120. The operation in step S190 can be achieved by a program according to a flowchart shown in, for example, FIG. 4B.

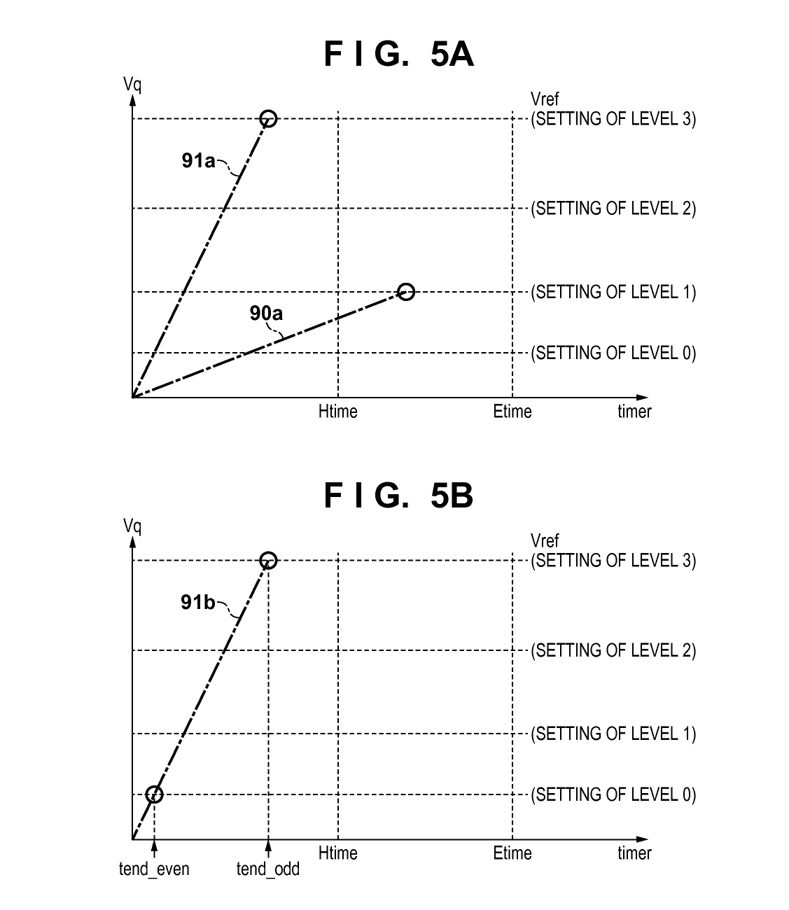

A series of operations in step S190 will be described in more detail herein with reference to FIG. 5A. FIG. 5A is a plot of an output potential Vq corresponding to the amount of charges accumulated in the photoelectric conversion unit 11ₖ on the ordinate as a function of “timer” on the abscissa in the test mode according to the second embodiment. Referring to FIG. 5A, an alternate long and short dashed line 90a indicates the case wherein the object is dark and charges are accumulated slowly, and an alternate long and short dashed line 91a indicates the case wherein the object is sufficiently bright and charges are accumulated early.

In the case of the alternate long and short dashed line 90a (when the object is dark and charges are accumulated slowly), the operation in step S190 is done when timer Htime is set. In step S191, the output c_out from the counter 111 is reset (c_out=0) in accordance with an instruction from the controller 150. In step S192, a reference potential Vref corresponding to the value of c_out is set. The reference potential Vref at this time is set upon selection of c_out by the selector 160 in accordance with an instruction form the controller 150. For example, when c_out=2, the reference potential Vref is set to “Level 2”. In step S193, the comparison unit 120 compares Vq and Vref. If the comparison result output from the comparison unit 120 is comp_out=Low (Vq<Vref), the process advances to step S196 (to be described later). If the comparison result output from the comparison unit 120 is comp_out=Hi (Vq Vref), the process advances to step S194. In step S194, the controller 150 determines whether the reference potential Vref is set to “Level 3” (whether c_out=3). If the reference potential Vref is “Level 3” (if c_out=3), the process advances to step S196 (to be described later). If the reference potential Vref is not “Level 3” (c_out≠3), the process advances to step S195. In step S195, the reference potential Vref is set one level higher than the current level (the value of c_out is incremented by one) in accordance with an instruction from the controller 150, and the process returns to step S193. The same procedure is repeated until the process advances to step S196 after Vq Vref is set in step S193, or the process advances to step S196 after the reference potential Vref changes to “Level 3” (c_out=3) in step S194. In step S196, control information is set in accordance with the reference potential Vref set in step S193 or S194. That is, the value of c_out at this time is stored in the storage unit 20ₖ as first control information in accordance with an instruction from the controller 150. Therefore, in the case of the alternate long and short dashed line 90a (when the object is dark and charges are accumulated slowly), c_out=1 is stored in the storage unit 20ₖ as first control information in steps S190 to S196 described above.

On the other hand, in the case of the alternate long and short dashed line 91a (when the object is sufficiently bright and charges are accumulated early), the output potential Vq reaches a reference potential Vref at “Level 3” when timer<Htime, and the process advances to step S220 after step S170, so the operation in step S190 is not done. This is because control information “3” initialized in an arbitrary storage unit 20ₖ is stored upon a reset process (step S120), so the reference potential Vref is set to the potential “Level 3” corresponding to the control information “3” in step S160.

In step S200, the controller 150 determines whether step S220 has been executed for all units k. If YES is determined in step S220, the process advances to step S230 (to be described later); otherwise, the process advances to step S210. In step S210, the next unit k is designated and the process returns to the operation in step S150. More specifically, if k<n, the next unit k is designated (the k value is incremented by one). If k=n, k is reset to k=1, and the next time is designated (for example, the value of “timer” is incremented by one). In step S220, the controller 150 ends the charge accumulation operation in the photoelectric conversion unit 11ₖ of the unit k, and temporarily holds the accumulated charges in the charge holding unit 13ₖ as the pixel signal q_out. Step S230 is an operation performed by the controller 150 after step S220 has been executed for all units k, and the pixel signal q_out is read out from an arbitrary charge holding unit 13ₖ. In step S240, the amplification factor setting unit 140 reads out the first control information stored in the storage unit 20ₖ to set an amplification factor. At this time, before step S240, control information can also be set again in step S190 of FIG. 4B in order to confirm the validity of the control information set in step S190 (not shown). In step S250, the pixel signal q_out read out in step S230 is amplified in accordance with the amplification factor set in step S240, and output. In step S260, the above-mentioned series of operations ends, and the function of the normal mode can thus be achieved.

In this way, in the normal mode, the focus detection apparatus 2 according to this embodiment outputs first control information which can control an accumulation operation in accordance with the luminance level of an object, and stores the first control information in each of the plurality of storage units 20ₖ.

The operation in the test mode will be described next. The test mode is executed upon irradiation with uniform light bright enough to allow the output potential Vq to reach a reference potential Vref at “Level 3” when timer<Htime (FIG. 5B). Also, the test mode can be achieved by the same flowchart (FIGS. 3A to 4B) as in the normal mode. Details of steps S100 to S110 are the same as in the normal mode, and a description thereof will not be given.

In step S120, a reset process (steps S120-S126) according to the test mode is performed, so control information “3” is stored in the storage unit 20ₖ of each odd-numbered unit, and control information “0” is stored in the storage unit 20ₖ of each even-numbered unit. This can be achieved by setting a mode setting terminal mode_sel=Hi in a selector 160s (FIG. 11B). The control information “3” may be output as the output c_out from the counter 111 (FIG. 11A) in accordance with an instruction from the controller 150, as described earlier. Also, the control information “0” may be fixed information prepared in advance. Details of steps S130 to S150 are the same as in the normal mode, and a description thereof will not be given.

In step S160, a reference potential Vref which is different when the unit k has an odd number and when it has an even number can be set. This operation will be described in more detail with reference to FIG. 5B. FIG. 5B is a plot of an output potential Vq corresponding to the amount of charges accumulated in the photoelectric conversion unit 11ₖ on the ordinate as a function of “timer” on the abscissa in the test mode according to the second embodiment. In the test mode, the operation is done upon irradiation with sufficiently bright, uniform light, so charges are accumulated early, as indicated by an alternate long and short dashed line 91b in FIG. 5B. Therefore, the output potential Vq reaches a reference potential Vref at “Level 3” or “Level 0” when timer<Htime, so the process advances to step S220 for all units k after step S170. Note that pieces of initialized control information “3” and “0” are stored in the storage units 20ₖ of odd- and even-numbered units, respectively, upon a reset process (step S120). Therefore, in step S160, a reference potential Vref at “Level 3” defined in the control information “3” is set for odd-numbered units, and a reference potential Vref at “Level 0” defined in the control information “0” is set for even-numbered units. As a result, in step S170, comp_out=Hi is obtained when timer=tend_odd for odd-numbered units, and when timer=tend_even for even-numbered units, and the process advances to step S220. Details of steps S170 to S210 are the same as in the normal mode, and a description thereof will not be given.

In step S220, charges accumulated for the time tend_odd are temporarily held in the charge holding unit 13ₖ of each odd-numbered unit as a pixel signal q_out, and charges accumulated for the time tend_even are temporarily held in the charge holding unit 13ₖ of each even-numbered unit as a pixel signal q_out. In step S230, therefore, the pixel signal q_out read out from the charge holding unit 13ₖ is different between odd-numbered units and even-numbered units. In step S240, the amplification factor setting unit 140 sets information (“3” in this embodiment) which specifies an amplification factor having a given unique value, regardless of the second control information stored in the storage unit 20ₖ. In step S250, the pixel signal q_out read out in step S230 is amplified in accordance with the amplification factor having the unique value set in step S240, and output. Therefore, if each of the plurality of sensor units 10ₖ has no malfunction resulting from factors associated with an adjacent sensor unit 10ₖ, the amplifier unit 30 alternately outputs different values for units k=1 to 2m. On the other hand, if each of the plurality of sensor units 10ₖ has a malfunction resulting from factors associated with an adjacent sensor unit 10ₖ, the amplifier unit 30 outputs the same value as that output from the adjacent sensor unit 10ₖ for the unit having the malfunction.

In this way, in the test mode, the focus detection apparatus 2 according to this embodiment stores pieces of different information in the storage unit 20ₖ of each odd-numbered unit and the storage unit 20ₖ of each even-numbered unit. For example, it is only necessary to store information for setting the amount of accumulated charges to a high reference in the storage unit 20ₖ of each odd-numbered unit as second control information, and information for setting the amount of accumulated charges to a low reference in the storage unit 20ₖ of each even-numbered unit as second control information. Pieces of information opposite to these pieces of second control information may be stored in the storage units 20ₖ of odd- and even-numbered units. With this operation, different amounts of charges are alternately stored in the plurality of sensor units 10ₖ, thus making it possible to detect a malfunction of each sensor unit 10ₖ due to factors associated with an adjacent sensor unit 10ₖ₋₁ or 10ₖ₊₁.

### Third Embodiment

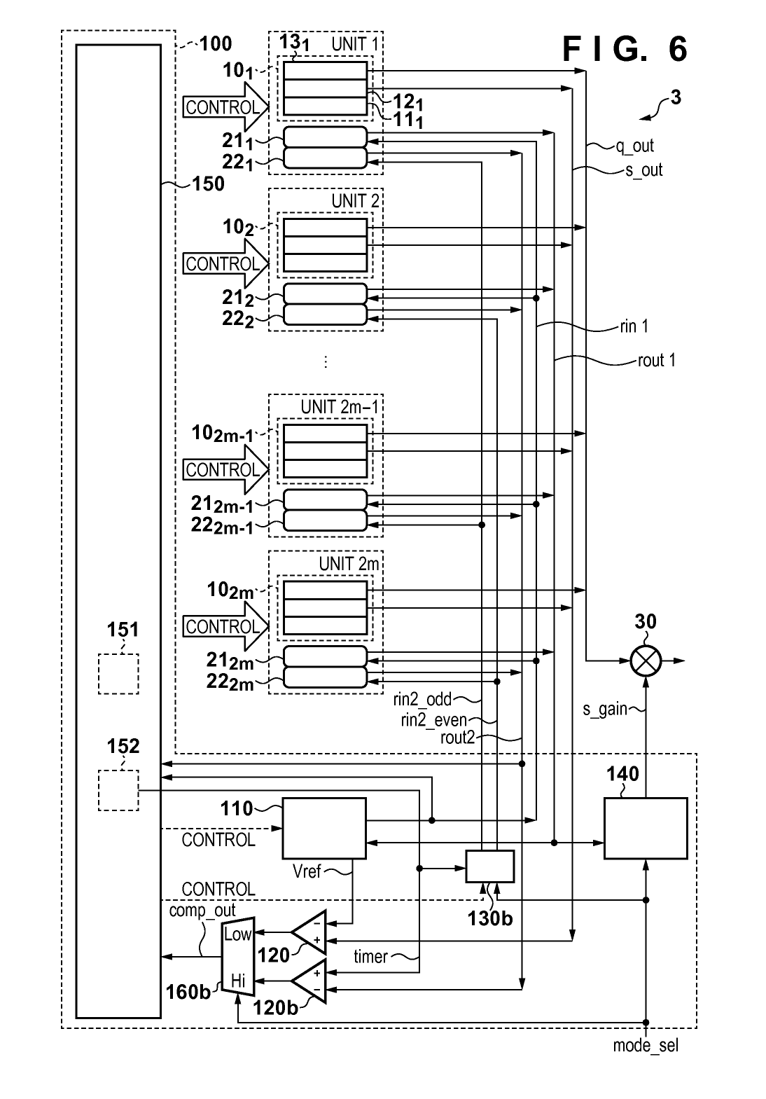

FIG. 6 shows a focus detection apparatus 3 according to the third embodiment to which the present invention is applied. This embodiment is different from the second embodiment in that in the former each of a plurality of storage units 20ₖ includes a first storage area 21ₖ which stores first control information, and a second storage area 22ₖ which stores second control information. The first storage area 21ₖ can store control information for setting a reference potential Vref. The second storage area 22ₖ can store control information for setting the charge accumulation time in a photoelectric conversion unit 11ₖ. Upon this operation, the internal configuration of a control unit 100 can be changed. That is, a comparison unit 120b and a selector 160b can be added, and an initial setting unit 130b can be adopted in place of the initial setting unit 130. In addition, lines which connect functional blocks to each other can be changed. That is, a comparison unit 120 receives the reference potential Vref and a signal s_out read out from a readout unit 12ₖ, and outputs their comparison result to the selector 160b. In this embodiment, the comparison unit 120 outputs Hi for s_out Vref. The comparison unit 120b receives the value of “timer” and control information rout2 read out from the second storage area 22ₖ, and outputs their comparison result to the selector 160b. In this embodiment, the comparison unit 120b outputs Hi for timer≧rout2. The selector 160b receives the outputs from the comparison unit 120 and comparison unit 120b, and selectively outputs one of them using a mode setting terminal mode_sel.

The initial setting unit 130b receives “timer” in place of c_out, and its two output terminals can be connected to signal lines for storing ring odd and ring even, respectively, in FIG. 6. Note that the first storage area 21ₖ has rin1 as an input and rout1 as an output, and the second storage area 22ₖ has rin2_odd and rin2_even as inputs and rout2 as an output. The initial setting unit 130b may have a configuration as shown in, for example, FIG. 11D, and can include selectors 160o and 160e to select the normal mode or the test mode as an operation mode upon setting of the mode setting terminal mode_sel. The initial setting unit 130b can output control information to ring odd and rin2_even of each second storage area 22ₖ in accordance with an instruction from a controller 150. In the normal mode, first control information “timer” associated with time can be stored in each of the plurality of second storage areas 22ₖ. On the other hand, in the test mode, pieces of second control information tq_odd and tq_even associated with times determined in advance can be stored in the plurality of second storage areas 22ₖ. That is, when the test mode, that is, a mode setting terminal mode_sel=Hi is set, rin2_odd is “tq_odd”, and rin2_even is “tq_even”. Therefore, control information “tq_odd” can be stored in the second storage area 22ₖ of each odd-numbered unit, and control information “tq_even” can be stored in the second storage area 22ₖ of each even-numbered unit. Also, although tq_odd>tq_even is set in this embodiment, the object of the present invention can be achieved in the opposite case as well.

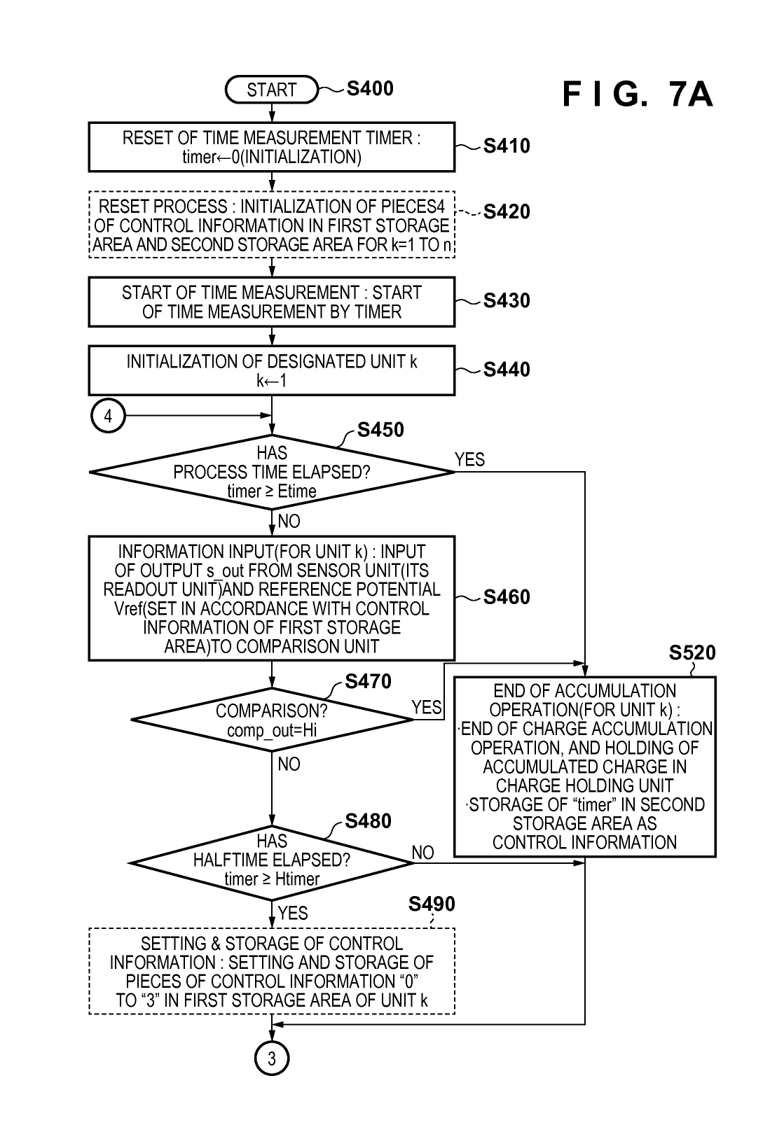

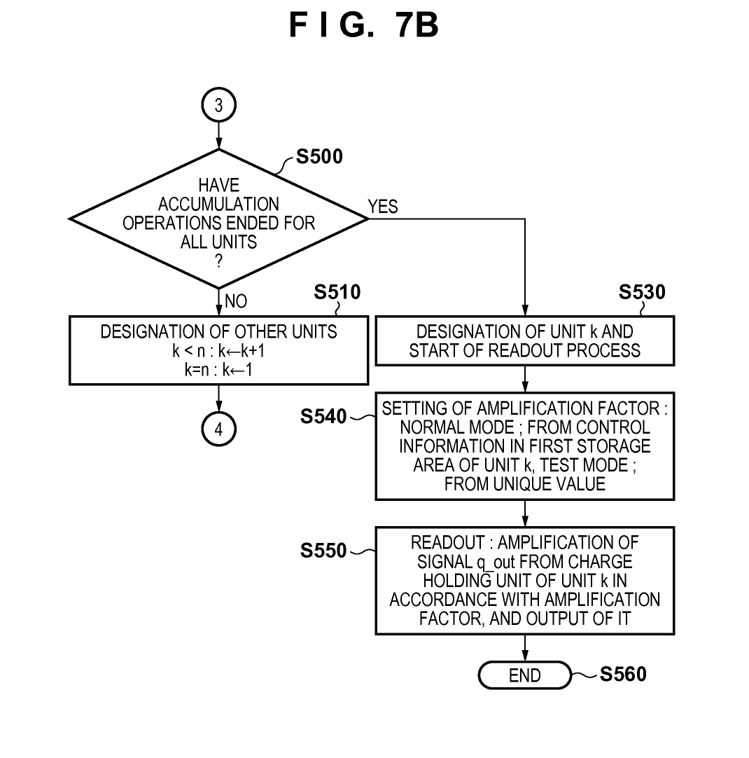

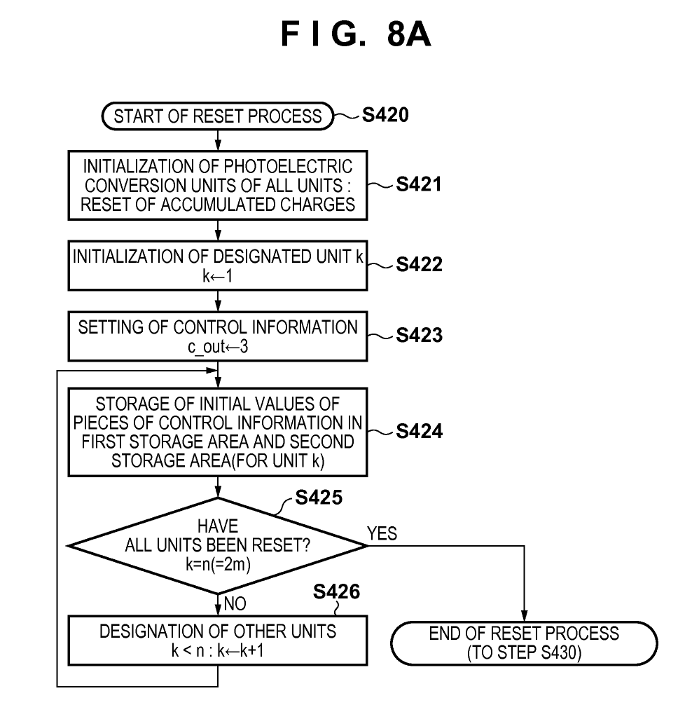

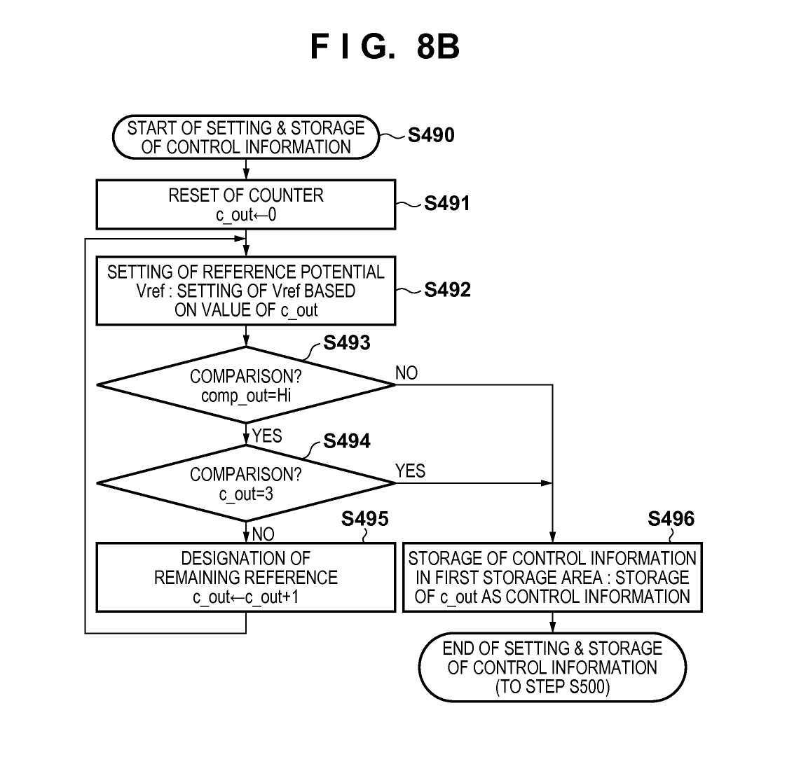

The operations of the focus detection apparatus 3, shown in flowcharts of, for example, FIGS. 7A to 8B, can be achieved by making the controller 150 execute the execution program. The operations in these flowcharts can also be achieved by the same execution program as in the second embodiment as the specifications of the operation blocks and lines which connect them to each other are changed. The operations in steps of these flowcharts, that produce effects different from the second embodiment, will be described below individually for the normal mode and test mode.

The operation in the normal mode will be described first. Details of steps S400 to S423 are the same as those of steps S100 to S123, respectively, and a description thereof will not be given. In step S424, the first storage area 21ₖ is initialized, so “3”, for example, is stored. This is because c_out (c_out=3) is set to “3” in step S423, as in the second embodiment. Then, “0” is stored in the second storage area 22ₖ. This is because the value of “timer” is reset (timer=j) in step S410. Details of steps S425 to S460 are the same as those of steps S125 to S160, respectively, and a description thereof will not be given.

In step S470, the output comp_out from the selector 160b is determined. Note that in the normal mode (mode_sel=Low), the selector 160b selects and outputs the output (the comparison result between Vref and s_out) from the comparison unit 120. If comp_out=Hi (s_out≧Vref), the process advances to step S520 (to be described later). If comp_out=Low (s_out<Vref), the process advances to step S480. Details of steps S480 to S510 are the same as those of steps S180 to S210, respectively, and a description thereof will not be given.

In step S520, the controller 150 ends the charge accumulation operation in the photoelectric conversion unit 11ₖ, and temporarily holds the accumulated charges in the charge holding unit 13ₖ as a pixel signal q_out. At the same time, in the normal mode (mode_sel=Low), the selectors 160o and 160e included in the initial setting unit 130b (FIG. 11D) output the values of “timer”. That is, control information (timer) associated with the time taken for this accumulation is stored in the second storage area 22ₖ. Details of steps S530 to S560 are the same as those of steps S230 to S260, respectively, and a description thereof will not be given.

In this way, in the normal mode, the focus detection apparatus 3 according to this embodiment outputs first control information for controlling an accumulation operation in accordance with the luminance level of an object, and stores the first control information in each of the plurality of first storage areas 21ₖ. Then, charges are accumulated in each of the plurality of sensor units 10ₖ up to a reference defined in the corresponding first control information. It is also possible to store control information associated with the time taken for this accumulation in each of the plurality of second storage areas 22ₖ, and use it in another focus detection operation again.

The operation in the test mode will be described next. The test mode can be achieved by the same flowcharts (FIGS. 7A to 8B) as in the normal mode. Although irradiation with sufficiently bright, uniform light is assumed in the test mode according to the second embodiment, it is not assumed in the test mode according to the third embodiment. Details of steps S400 to S423 are the same as in the normal mode, and a description thereof will not be given. In step S424, in addition to initializing the first storage area 21ₖ (storing, for example, “3”), “tq_odd” can be stored in the second storage area 22ₖ of each odd-numbered unit as second control information, and “tq_even” can be stored in the second storage area 22ₖ of each even-numbered unit as second control information. This is because in the test mode (mode_sel=Hi), the selectors 160o and 160e included in the initial setting unit 130b (FIG. 11D) output “tq_odd” and “tq_even”, respectively. Details of steps S425 to S460 are the same as in the normal mode, and a description thereof will not be given.

In step S470, the output comp_out from the selector 160b is determined. Note that in the test mode (mode_sel=Hi), the selector 160b selects and outputs the output (the comparison result between “timer” and rout2) from the comparison unit 120b. If comp_out=Hi (timer≧rout2), the process advances to step S520 (to be described later). If comp_out=Low (timer<rout2), the process advances to step S480. Details of steps S480 to S510 are the same as in the normal mode, and a description thereof will not be given.

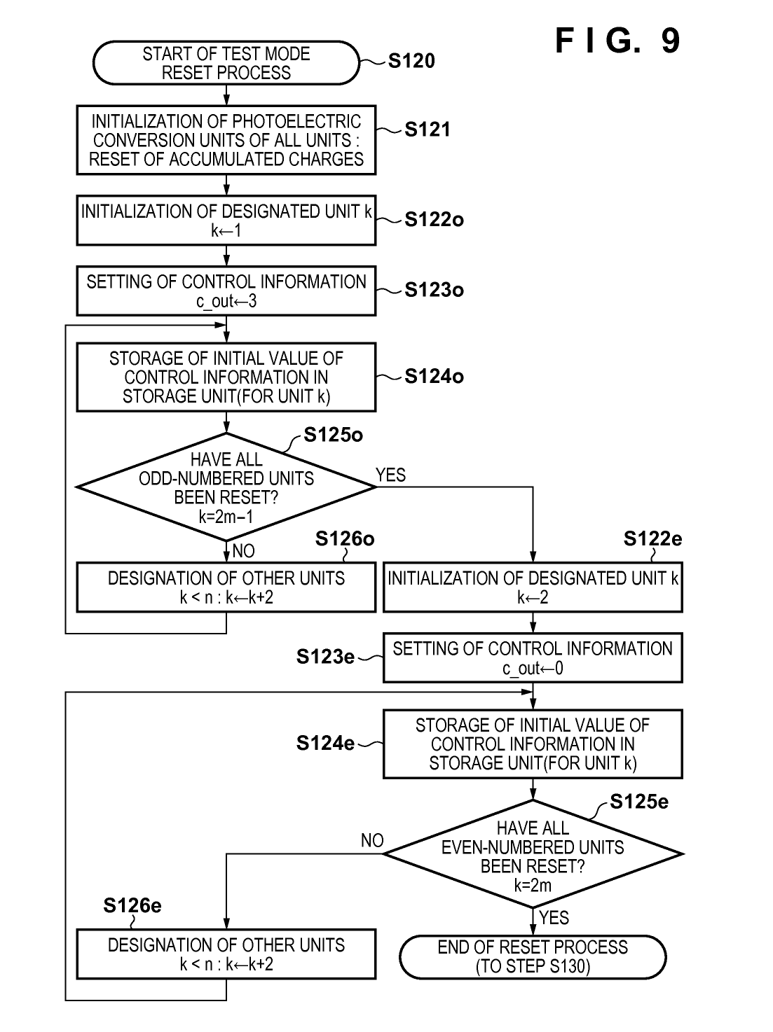

In step S520, the controller 150 ends the charge accumulation operation in the photoelectric conversion unit 11ₖ, and temporarily holds the accumulated charges in the charge holding unit 13ₖ as a pixel signal. This operation will be described in more detail with reference to FIG. 9. FIG. 9 is a plot of an output potential Vq corresponding to the amount of charges accumulated in the photoelectric conversion unit 11ₖ on the ordinate as a function of “timer” on the abscissa in the test mode according to the third embodiment. In the test mode according to this embodiment, a charge accumulation operation can be controlled with reference to the time defined in the second control information. That is, as for a charge accumulation operation in the photoelectric conversion unit 11ₖ of each odd-numbered unit, step S520 is performed for comp_out=Hi when timer≧rout2=tq_odd is set in step S470. On the other hand, as for a charge accumulation operation in the photoelectric conversion unit 11ₖ of each even-numbered unit, step S520 is performed for comp_out=Hi when timer≧rout2=tq_even is set in step S470. Details of steps S530 to S560 are the same as in the normal mode, and a description thereof will not be given.

In this way, in the test mode, the focus detection apparatus 3 according to this embodiment stores pieces of different information in the second storage area 22ₖ of each odd-numbered unit and the second storage area 22ₖ of each even-numbered unit. Then, charges are accumulated in each of the plurality of sensor units 10ₖ up to a reference defined in the second control information stored in the corresponding second storage area 22ₖ. In this embodiment, information for setting a long charge accumulation time is stored in the second storage area 22ₖ of each odd-numbered unit as second control information, and information for setting a short charge accumulation time is stored in the second storage area 22ₖ of each even-numbered unit as second control information. Pieces of information opposite to these pieces of second control information may be stored in the second storage areas 22ₖ of odd- and even-numbered units. With this operation, different amounts of charges are alternately stored in the plurality of sensor units 10ₖ, thus making it possible to detect a malfunction of each sensor unit 10ₖ due to factors associated with an adjacent sensor unit 10ₖ₋₁ or 10ₖ₊₁. It is also possible to similarly detect a malfunction of each second storage area 22ₖ.

### Fourth Embodiment

In the above-mentioned second and third embodiments, the normal mode and the test mode are selected by switching the mode setting terminal mode_sel set in the control unit 100. However, as in the fourth embodiment to be described below, it is also possible to store execution programs of the normal mode and test mode in a program memory 151 in advance, and select, read out, and execute one of these programs, instead of switching a mode setting terminal mode_sel. One of the execution programs can be selected in accordance with, for example, an instruction from an external interface. In this case, the mode setting terminal mode_sel may be fixed or may not be set.

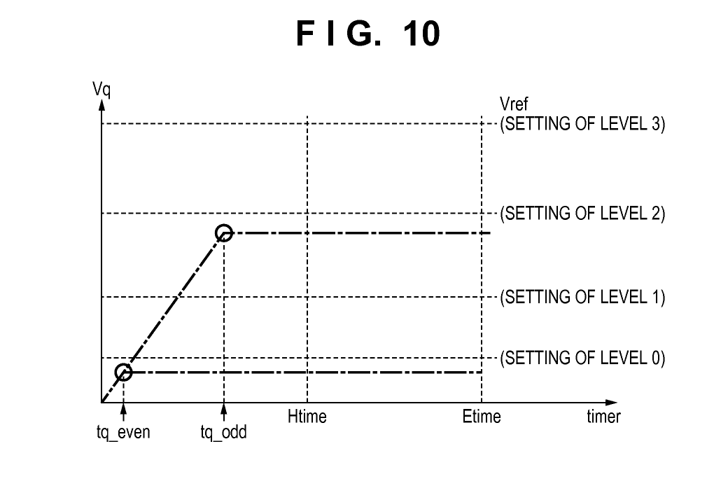

For example, an execution program according to the flowcharts (FIGS. 3A to 4B) in the second embodiment can be directly used in the normal mode, while an execution program different from the former can be executed in the test mode. With this operation, the same effect as in the focus detection apparatus 2 can be achieved without using the mode setting terminal mode_sel. FIG. 10 illustrates an example of a detailed flowchart of a reset process (step S120) in the test mode according to the fourth embodiment. Details of steps S120 and S121 are the same as in the second embodiment, and a description thereof will not be given. In steps S122o to S126o, control information to be stored in a storage unit 20ₖ of each even-numbered unit is initialized (for example, “3” is set (step S123o)), and stored in this storage unit 20ₖ (steps S122o, S124o, S125o, & S126o). Control information “3” having the initial value may be stored based on, for example, an output c_out from a counter 111 (FIG. 11A), in accordance with an instruction from a controller 150, as in this embodiment. In steps S122e to S126e, control information to be stored in a storage unit 20ₖ of each even-numbered unit is initialized (for example, “0” is set (step S123e)), and stored in this storage unit 20ₖ (steps S122e, S124e, S125e, & S126e). Control information “0” having the initial value may be stored based on, for example, the output c_out from the counter 111 (FIG. 11A), in accordance with an instruction from the controller 150, as in this embodiment. The process then returns to step S130. Details of step S130 and subsequent steps are the same as in the second embodiment, and a description thereof will not be given. With this operation, pieces of initialized control information “3” and “0” are stored in the storage units 20ₖ of odd- and even-numbered units, respectively, thus making it possible to achieve the same effect as in the second embodiment.

Although four embodiments have been described above, the present invention is not limited to them, and the object, state, use purpose, function, and other specifications can be changed as needed, so the present invention can also be practiced by other embodiments, as a matter of course. The sensor unit serves as, for example, a CCD image sensor or a CMOS image sensor, and may serve as any other sensors. Although the storage unit is assumed to be a digital memory such as an SRAM in this embodiment, an analog memory can also be used. Although the execution program is stored in the program memory included in the controller in this embodiment, it may be read out from a peripheral storage device in accordance with an instruction from a microcomputer or other peripheral circuits. Note that the storage device includes, for example, a ROM, floppy disk, hard disk, optical disk, magnetooptical disk, CD-ROM, CD-R, magnetic tape, and nonvolatile memory card. The execution program may partially or wholly be executed by, for example, the OS running on the computer, together with or in place of the controller.

Also, although a focus detection apparatus included in a camera has been described in the above-mentioned embodiment, the concept of the camera includes not only an apparatus mainly intended for image capture, but also an apparatus (for example, a personal computer and a portable terminal) accessorily provided with an image capture function. A calculation unit which executes a focus detection process may be included in the focus detection apparatus. The camera can include the focus detection apparatus according to the present invention illustrated as each of the above-mentioned embodiments, a solid-state image sensor, and a processing unit which processes a signal output from the solid-state image sensor. The processing unit can include, for example, an A/D converter and a processor which processes digital data output from the A/D converter. A focus detection process can also be performed by the processing unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-246855, filed Nov. 10, 2011, which is hereby incorporated by reference herein in its entirety.

What is claimed is:

1. A semiconductor device including a plurality of sensor units, and a plurality of storage units corresponding to the plurality of sensor units, respectively, the device comprising:
a controller which
in a normal mode, sets a plurality of pieces of first control information based on outputs from the plurality of sensor units, respectively, stores the plurality of pieces of first control information in the plurality of storage units, respectively, and accumulates charges in each of the plurality of sensor units up to a reference defined in the corresponding first control information, and
in a test mode, stores a plurality of pieces of second control information for tests determined in advance in the plurality of storage units, respectively, accumulates charges in each of the plurality of sensor units up to a reference defined in the corresponding second control information, and tests the plurality of sensor units based on the amounts of charges accumulated in the plurality of sensor units.

2. The device according to claim 1, further comprising:
an amplifier unit,
wherein said control unit sets an amplification factor based on the first control information stored in each of the plurality of storage units in the normal mode, and sets an amplification factor based on the second control information determined in advance for each of the plurality of storage units in the test mode, and
said amplifier unit amplifies a signal output from said sensor unit in accordance with the set amplification factor, and outputs the amplified signal.

3. The device according to claim 1, wherein
each of the plurality of storage units includes a first storage area which stores the first control information, and a second storage area which stores the second control information, and
the first storage area and the second storage area are selectively used in the normal mode and the test mode.

4. The device according to claim 1, wherein said control unit operates in accordance with a program.

5. A focus detection apparatus comprising:
a semiconductor device defined in claim 1; and
a calculation unit which executes a focus detection process based on the output from said semiconductor device.

6. A camera comprising:
a focus detection apparatus defined in claim 5;
a solid-state image sensor; and
a processing unit which processes a signal output from said solid-state image sensor.
